(19) United States
(12) Patent Application Publication
(10) Pub. No.: US 2010/0053876 A1
(43) Pub. Date: Mar. 4, 2010

(54) LAPTOP COMPUTER

(75) Inventors: Jannis Widmer, Maienfeld (CH); Hartmut Esslinger, Palo Alto, CA (US)

Correspondence Address: MORRISS OBRYANT COMPAGNI, P.C., 734 EAST 200 SOUTH, SALT LAKE CITY, UT, 84102, US

(73) Assignee: Dreamcom Corporation, Chur (CH)

(21) Appl. No.: 12/298,007

(22) PCT Filed: Apr. 23, 2007
(86) PCT No.: PCT/CH07/00194

§ 371 Date: Aug. 17, 2009

(30) Foreign Application Priority Data
Apr. 21, 2006 (CH) 664/06

(51) Int. Cl. G06F 1/16; H05K 7/00

(52) U.S. Cl. 361/679.27; 361/679.55

(57) ABSTRACT

The invention relates to a laptop computer with at least one first body component (23) constituting an interface (33) and one second body component (25) constituting a display (35) that can be swiveled on the axis of a joint (21) around the first body component (23) and connected to it. The two body components (23,25) together form the body of a computer. The body of the computer contains at least a CPU, a data storage module, and an energy storage device. In addition, a docking module (27) is provided that can be connected to the body and disconnected from the body of the computer with a plug connection and that features at least one network device and one drive. This can be disconnected from the rest of the laptop. In addition, the first body component, the second body component, and the docking module form three flexibly interconnected body components (23,25,27) that can be opened in a Y-shaped way so that two body components (23,27) serve as a stand for the body component (25) that is provided with the display (35).

The invention relates to a laptop computer.

A laptop or notebook differs from a fixed desktop computer in being compact and portable, i.e. that among other things it is equipped with an energy storage device. Laptop means a portable computer which can be operated with programs suitable for personal computers (regardless of whether it is an IBM compatible or not) which combines in one piece of equipment the necessary computer components such as CPU, RAM storage unit, graphics processor and similar on a motherboard, and energy storage device, interface and display, and which can be folded for transport so that the display and interface are protected.

For our purposes, a tablet PC is also considered to be a laptop whose screen is interactive and as a rule—except for the hard disk or another data storage module which assumes the function of a hard disk—does not contain an integrated drive and has a correspondingly small size.

According to this patent, a laptop differs from palmtops, etc. in being provided with full versions of the usual computer programs, a practically full-function interface (as a rule with keyboard and touchpad) and a relatively large display of at least 12 inches.

All laptops comprise an interface, i.e. an input window, in particular an interactive screen, a keyboard and a touchpad or similar. Every laptop also possesses a display, which is a surface displaying a picture; currently that is normally a TFT screen measuring 12″ to 17″ diagonally.

A first body component provided with the interface and a second body component equipped with the display that can be swiveled on the axis which can be opened at an angle to be able to operate the interface and to be able to view the display at the same time. The interior of the component houses the necessary computer components, a data storage module (e.g. a hard disk), as well as an energy storage device (in particular a rechargeable battery pack). The energy storage device can be designed to be connected to the component or housed by the component. Also, an optical drive (CD and/or DVD) is usually integrated into the component, often a diskette drive as well. Further, as a rule, a laptop is provided with several, possibly different receptacles for plugs (e.g. USB, headphones, etc.). These plug connections or corresponding wireless connection devices allow the simple connecting of external equipment such as external mice, external drives, music equipment, speakers, cameras and film equipment, storage media, transmitters and receivers for, for example, wireless LAN's, joysticks, projectors, printers, scanners, headphones, microphones and much more.

Because laptops are so compact special attention must be paid to cooling the processor. This is all the more so because newer processors tend to be higher performance and therefore consume more power and generate more heat.

A disadvantage of known laptops is that the display cannot be placed at an ergonomic height above the interface or table with respect to the user. From an ergonomic perspective, then, the laptop is not a full-featured replacement for a desktop personal computer.

Another disadvantage of known laptops is that in the manufacture of laptops the entire component and the space distribution in the component and/or the configuration of the components arranged in the component have to be redesigned and differently manufactured for each different display size.

A further disadvantage is that the display size of a laptop cannot be changed, i.e. for work at a workstation has to use the same size display as when working on the road.

Another disadvantage of known laptops is that every component with which the laptop is equipped always has to be taken along with the laptop. If, for example, an external display is connected to the laptop, there are two displays. If no alternate data medium drive is required or an external DVD drive is connected, the integrated DVD drive becomes superfluous.

It is therefore the task of the invention to propose a laptop whose features overcome the aforementioned disadvantages.

It is particularly the task of the invention to create a laptop in which the manufacture of models with different size displays is simplified as much as possible. In addition, it should be more flexible in terms of this use, e.g. as desktop computer, compact laptop or tablet PC.

Another particular task of the invention is to create a laptop whose display can be arranged in an ergonomically optimized position with respect to the user.

It is another task of the invention to create a laptop to achieve an efficient cooling of the processor with simple means.

The invention starts with a laptop which comprises a first body component for an interface and a second body component that can be swiveled on the axis of a joint around the first body component and connected to it. Together the two body components form the body of the computer. The body of the computer of this laptop houses the necessary computer components, a data storage module, and an energy storage module.

In order to solve the task of the ergonomic configuration of the display, it is proposed that in a laptop with interface and display according to the introductory clause of Claim 1, the component be provided with three articulated body components which can be opened into a Y shape. Two of the body components can therefore be used as a stand for the body component provided with the display. The Y-shaped set-up makes it possible to adjust the height of the screen using the support.

In order to make the laptop as light and small as possible, some bulkier components can be moved from the computer body to the docking module. Advantageously, then, the laptop is provided with a docking module that can be connected to the computer body which contains at least one drive, and preferably also a power supply. This docking module then forms one of the three arms of the Y. A plug connection between docking module and computer body guarantees not only an electrical connection but also a mechanical connection which defines the position of the connected parts to each other. Thus docking module and computer body, i.e. docking module, display body component and interface body component form a single piece of equipment.

So as to retain the most ergonomic conditions possible for the workstation, an external interface is preferably connectible to the docking module. The connection is in particular wireless, can however be done with a wire connection and comprises an external keyboard and an external mouse. These can be connected to the laptop. Together, the interface body component of the laptop and the docking module can be used as a display foot. The interface body component of the laptop can also have a wireless connection with the electronics housed in the computer body, so that the interface body component can be separated from it in order to operate the computer. Then the first body component containing the data storage unit, possibly together with the docking module, can be used as a foot for the free-standing display.

So as to meet this foot function in an optimum fashion, the docking module purposefully contains a flat component and a receptacle for a plug connector. The receptacle can be swiveled with the flat component of the docking module. It can preferably be plugged into the first body component. This creates the possibility of spreading the first body component (without or without interface, with or without interface body component on it) and the second body component in a Y-shaped fashion with the display. In so doing, the two arms which can be positioned on a support of the inverted Y are formed by the docking module and the first body component (without or with interface body component). The third arm is vertical and formed by the second body component with the display body component.

In this way, the computer body, together with the display body component and the docking module form a display which can be set up on a table, which has integrated in it all of the components necessary for a computer workstation.

Thanks to the Y-shaped configuration all of the components are exposed to the air and thus well ventilated.

Needless to say, these arms must provide great resistance against relative pivoting so that a pivoting does not occur automatically under own weight, but rather can be created when desired. It is possible to provide a stop for pivoting. The flexibly connected parts therefore resist pivoting in different swivel positions by being, for example, locked, clamped or fixable.

The display can be advantageously provided in a separate display body component which is mounted on the second body component. Similarly, the interface can be provided in a separate interface body component which is mounted on the first body component. The length and width of the first housing is in this case advantageously smaller than the length and width of the interface body component mounted on it. This not only creates an optically attractive, flat appearance of the laptop for which the thickness of the interface body component and the display body component define the image, but it also creates possibilities for moving the interface body component and the second body component and/or between the interface body component and the first body component with respect to each other. The connection devices are thereby arranged independent of the display size always on the back of the display body component and the interface body component. In addition to the second body component, this creates room for a guide rail on the display body component.

On the other hand, the docking module essentially has the same length and the same width as the two body components of the computer body (without display body component and without interface body component). Its thickness is determined by the thickness of the drive or, possibly, by the thickness of the AD-adapter/charger. In addition to a charger, one or more drives, it can also contain a card reader, an additional energy storage device, jacks for speakers, etc.

If the display body component, as provided in a preferred embodiment, can be connected to the second body component, the display body component can also be replaced and exchanged for one with a larger display. This has the aforementioned advantage that a larger screen can be used at a workstation than on the road. Pluggability makes it easier to exchange, making it a simple matter which not only makes a laptop easier to use but also simplifies production, in particular assembly.

According to another aspect of the invention, a laptop according to the introductory clause of Claim 1 the solution to optimization of cooling the computer components is based on the assumption that the cooling of the processor can be significantly improved if the CPU is housed in the second body component. Advantageously, the body component frame of the second body component is made of metal.

Advantageously, in this laptop the display is housed in a display body component, and the display body component is mounted on the second body component and is movably mounted with respect to the second body component and/or is interchangeable with a display body component with a different display size.

For such a piece of equipment, the above task to simplify the production of laptop types with different size displays is solved inventively by housing the display in a separate display body component which is mounted on the second body component. Alternatively or preferably in addition the interface is housed in a separate interface body component which is mounted on the first body component. Together, the first and second body components form a computer body in which the computer components are housed, and on which the interface and the display are fixed in their own body components which correspond to the size of the display. The connectors to the different sized display or interface body components are standardized and coordinated to the first and/or second body components of the computer body found in all types. Such a display body component and/or interface body component has an essentially closed back. The body component can be set up with the back on which the second and/or first body component is mounted so that advantageously an outer surface of the display body component or interface body component sits on another surface of the second or first body component. This back is provided with connectors to connect the first body component and the interface body component or the second body component and the display body component to each other, Also, electrical connections are present for the components to be connected. These connections are preferably plug connectors for the display and plug connectors or wireless connectors for the interface.

Setting up the display body component on the second body component, as well as setting up the interface body component on the first body component have the advantage of being able to produce the respective first or second body component with the components it houses independent of the size of the display. Depending on the design of the laptop, only display and interface body components having the desired size will be mounted on the two equal size produced body components of the computer body. The connectors on the different size interface and/or display body components are always the same design and therefore fit regardless of the display size with/on the first and/or second body components having the same size and design.

Providing the display in a display body component makes it possible to store/load this display body component by sliding it into the second body component. If the display body component is pulled away from the axis of the joint and movably mounted, that has the advantage that the display can be lifted to an ergonomic height above the interface than previously due to its fixed, swivel angle-dependent configuration. The display is—vertical to the swivel axis—movable from the joint so as to be able to arranged as close as possible to eye height and can then be move back on the joint so that the laptop can be closed to the smallest size possible.

As move mechanism it is proposed that at least one stop rail and at least one stop tooth working together with the stop rail is connected to the first body component and/or with the display body component, so that the display body component can be used in a number of move positions with respect to the second body component and can be released to be move back.

Advantageously, the stop rail contains a stop tooth associated with the stop rail which engages with a row of teeth.

To stop and release the stop, the stop rail is advantageously movable oblique to the longitudinal extension of the row of teeth. Engagement of the row of teeth and the stop tooth can be achieved and released by sliding the stop rail.

If there are two stop rails and two rows of stop teeth which stop rails can be moved together and apart, and which can be actuated by a common actuation device, the display body component is stopped in two separate positions so that a wobbling of the display body components around a single stop point is excluded. In addition, the two stop rails can be pre-stressed with respect to each other using a spring, whereby a simple pulling together of the rails (or spreading of the stop rails) can be performed, for example, against the spring energy via a link for the release motion.

Advantageously, the stop tooth or stop teeth are arranged on the display body component. Or to put it another way, it is useful to provide the more complex part of the stop device on the second body component supporting the display body component. If the display is replaced, this part of the stop device can be used again.

The display body component and the second body component are advantageously mounted on each other to an adjustment plate, which adjustment plate has a swivel connection between two rods forming the adjustment plate and one tilt point on each of the four ends of the rods. Two of the tilt points are mounted on the display body component or on a component moving with the display body component. The two other tilt points are mounted on the second body component or on a component sliding together with the second body component.

Advantageously, two tilt points are mounted to inclined links toward each other. These links are advantageously so inclined that moving the display body component with respect to the second body component results both in a pivoting of the two rods of the adjustment plate to each other and also to a resulting movement of the tilt points mounted in the inclined glide plates in the direction of the movement of the display. The inclination of the links results in the adjustment plate being moved in the move direction thereby remaining centered.

Advantageously, the rods of the adjustment plate are prestressed against each other with a spring so that a movement from the axis of the joint is supported between the first and the second body component.

Much the same applies to the interface body component. If it is movably mounted on the first body component moved away from the axis of the joint and back again, the distance between interface and display can be increased, and with it the distance between the eyes of the interface user and the display. A sliding mechanism for the display body component can be exactly like this.

Providing a display body component which can be mounted on the computer body also has the advantage that the display body components can be designed interchangeably. The display body component and the second body component is also equipped with interoperative connector devices. The desktop can therefore be alternately equipped with two display panels having different sizes which when the user so requires can exchange them by simply removing and unplugging the one and inserting and installing the other. Such displays equipped with a standardized electrical plug connection and a standardized mechanical connector device can be exchanged by the user. Therefore an inventive laptop model can be sold in shops which has not only displays of the same size and different specifications (e.g. resolution, contrast, etc.), but most of all displays with different sizes. Thanks to this preferred embodiment of the invention it is possible for the user to equip the laptop with a larger display in the office, while using a smaller display on the road. The interface body component is advantageously as large as the smaller of the two display body components.

A further advantage of this display housed in its own body component consists of the fact that in case of a display defect only the display with the display body component needs to be replaced or exchanged at the shop. Therefore, for the purpose of a display replacement, data contained on data storage units must not be given out to other. This advantage guarantees the confidentiality of possibly sensitive data.

The interface body component can also be designed to be replaceable. For this purpose, the interface body component and the first body component are equipped with mechanically interactive connector devices. These make it possible to equip the same computer body with an interface body component customized for the customer. For example, an interactive screen can be exchanged for a keyboard. A keyboard complying with one standard can be replaced with one using another standard. The user can choose between an interface with a touchpad or another device to operate the mouse cursor. In short: The desired laptop can be assembled in a modular fashion, whereby a computer body with different display body components, interface body components and, as will be explained below, if necessary docking modules.

Unlike conventional laptops in which the processor is housed between the base of the laptop and the keyboard, in the inventive laptop the CPU is advantageously provided in the second body component. This configuration has the advantage that the CPU has a cooling surface which borders on the ambient air and is not covered. In operation, this cooling surface is essentially vertical. This orientation additionally supports convection and therefore cooling of the processor. The cooling performance used to cool the processor is thereby significantly increased. In order to further enhance heat release, the second body component is advantageously equipped with a body cover made of metal, which forms the cooling surface. The cooling capacity is further increased if the display can be moved with respect to the second body component. The processor is enclosed in a flat package with a metal jacket, which jacket is always exposed to the ambient air when the display is moved.

The second body component is also supplied with air holes, and the second body component is equipped with a fan to actively cool the processor. The air holes are pointed upward when the laptop is open because they are located on the front side of the second body component provided opposite the joint. Heated air escapes from these air holes. Fresh air enters through air holes near the joint into the second body component or flows on the axial front surfaces of the joint body in the joint body and from there to the flat part of the second body component. The supply direction of air from below to above corresponds to the flow direction of the air which is created by the warming. In such a configuration the danger of covering the ventilation holes is virtually eliminated.

Advantageously, the energy storage device and the data storage module are provided under the interface body component in the first body component. This first body component can also contain for example an optical drive for alternative data media.

The aspects described above can be combined in any way desired. The features listed in the dependent claims can be formulated dependent on each of the independent claims.

The subject of the invention is described in detail below using the examples shown in the drawing. It shows:

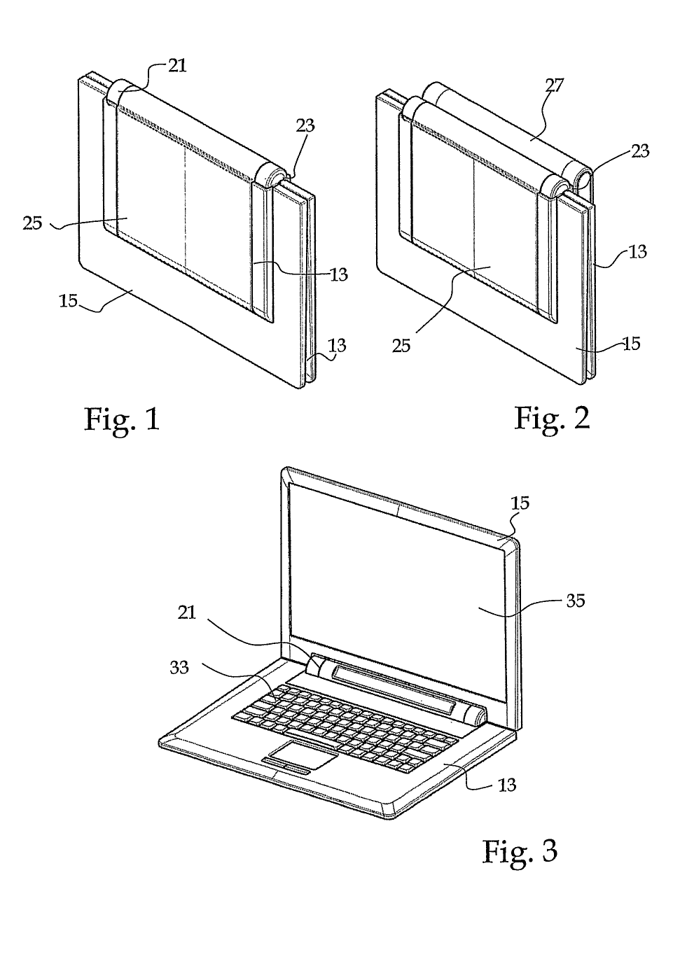

FIG. 1: A perspective view of the closed laptop without docking module

FIG. 2: A perspective view of the closed laptop with docking module

FIG. 3: A perspective view of the open laptop

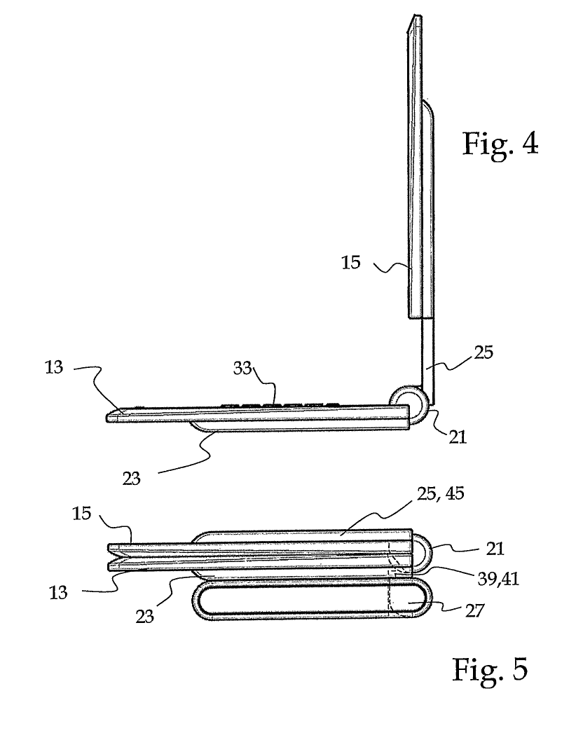

FIG. 4: A side view of the open laptop without docking module

FIG. 5: A side view of the closed laptop with docking module

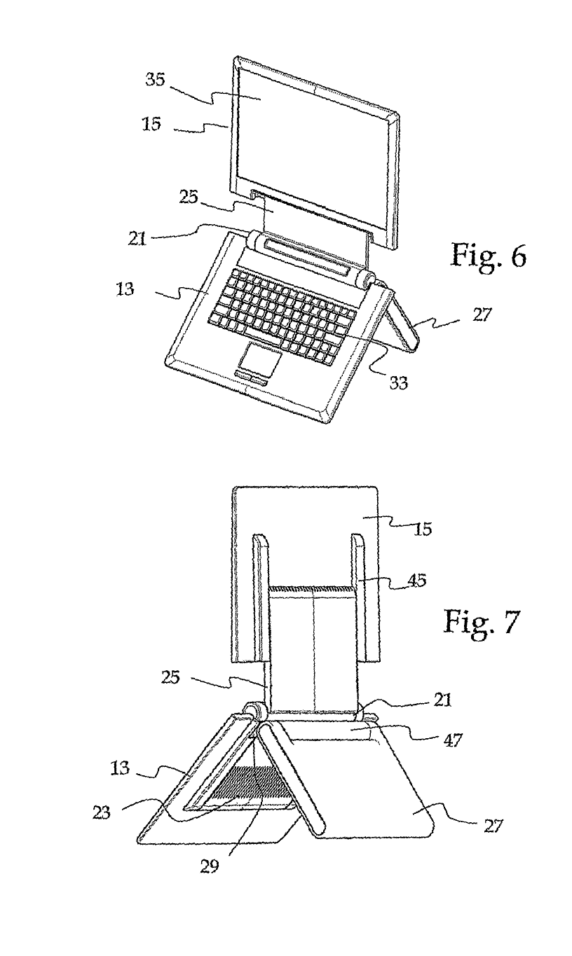

FIG. 6: A perspective view of the laptop in Y position and with protruding display body component

FIG. 7: A perspective view of the laptop in Y position from the back

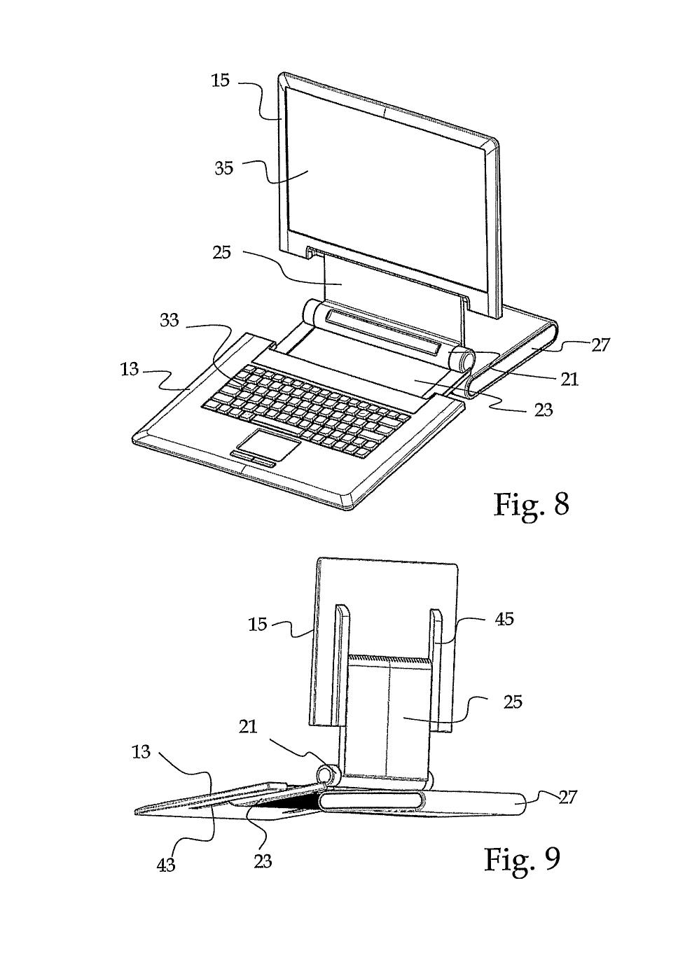

FIG. 8: A perspective view of the laptop with ergonomically tilted and extended keyboard

FIG. 9: A perspective view of the laptop in the same position as in FIG. 8, but from the back and below

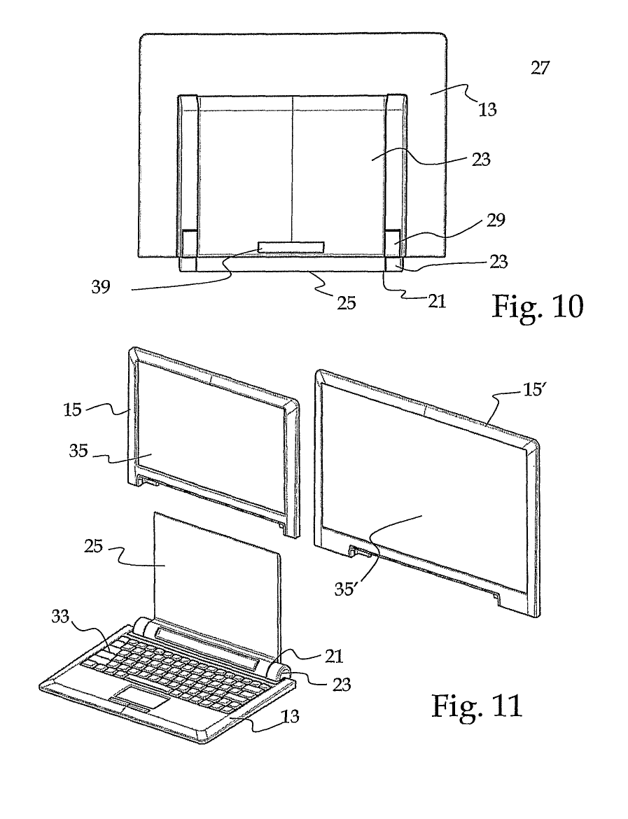

FIG. 10: A bottom view below the interface and first body component

FIG. 11: A perspective view of a component sets for the laptop with a smaller and a larger display body component

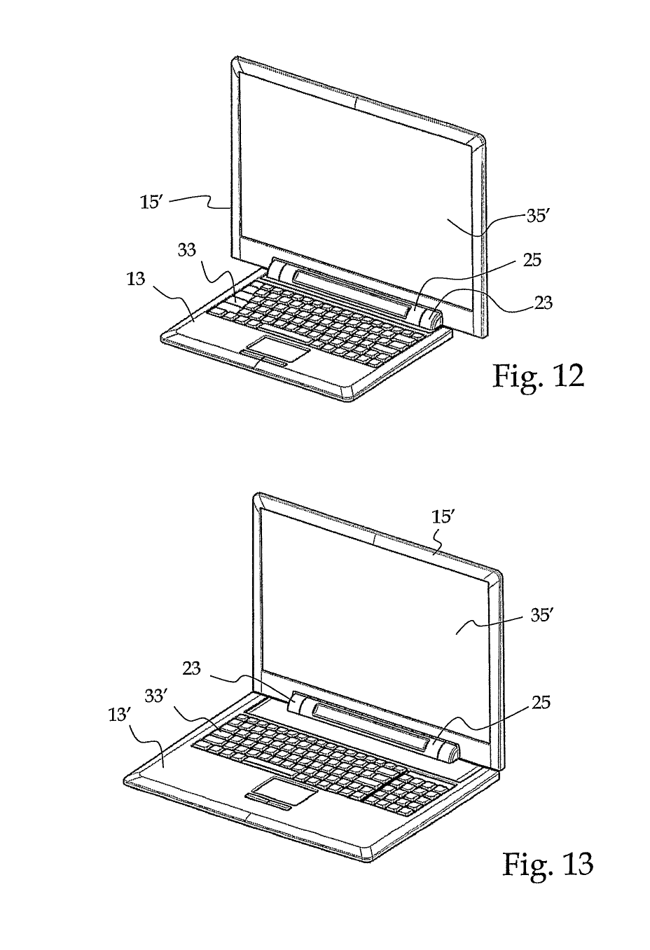

FIG. 12: The laptop with the mounted 17″ display and the smaller interface

FIG. 13: The laptop with the 17″ display and the larger interface expanded by the numeric keyboard

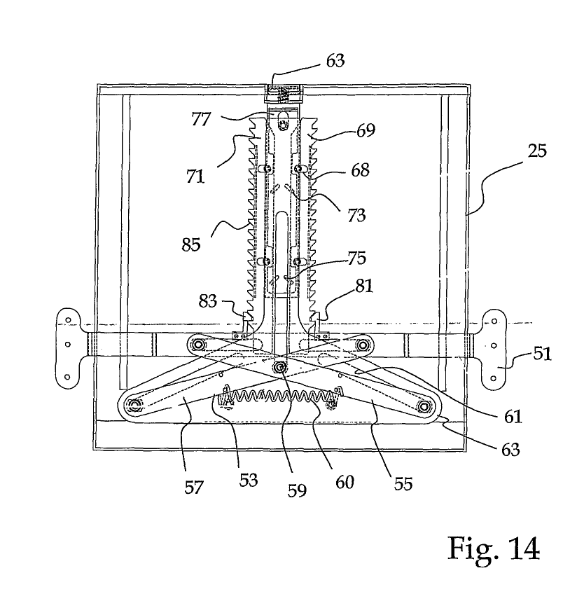

FIG. 14: A sliding mechanism with a stop device for the arrangement of the display body component on the second body component.

The laptop shown in FIGS. 1, 3 and 4 is substantially flat. What can be seen in FIG. 1 is an interface body component 13 with an interface 33 and a display body component 15 with a display 35. The two body components 13 and 15 are flexibly connected via a joint 21.

On the back of the interface body component 13 and on the back of the display body component 15, there can be seen a first body component 23 and a second body component 25 of a computer body housing the computer. The first body component 23 contains a hard disk or another, equivalent data storage module, and, for example, a lithium-ion battery. Another drive can be provided in it. The second body component 25 contains the CPU, that is, the motherboard with the processor, and the other necessary computer components, such as RAM, graphics processor, etc.

The two body components 23 and 25 form the computer body together with the joint 21. The interface body component 13 and the display body component are mounted on this computer body. According to these figures, the laptop comprises four body components. The computer body consisting of two body components 23, 25 forms the essentially same components found in the different embodiments of the inventive laptop. The display body component has a size corresponding to the display, and therefore can be suited for a 12″, a 15″ or a 17″ display. The interface body component has a corresponding to the display body component and the screen size is therefore selected accordingly. This version of the laptop is characterized by a very slim appearance. In this embodiment the laptop is about 44 mm thick, whereby the optically effective thickness through the interface body component and the display body component is only 24 mm.

The laptop shown in FIG. 2 and FIGS. 5 through 9 is supplemented by a docking module 27. The docking module 27 is connected to the computer body, i.e., with the first body component 23, through a plug connection 39, 41 (FIG. 5). The docking module contains an optical drive and a power unit with charger (not shown). The docking module is ca. 15 to 20 mm thick.

The docking module 27 is provided with jacks for an external keyboard, an external mouse, external drives, etc. (not shown).

The docking module 27 can be carried along with the laptop; it can, however, also remain installed at a fixed workstation. For that reason it can be connected to the computer body and the plug connection 41 on the docking module 27 via an interface 39 (FIG. 10) visible in FIG. 5 and can be disconnected from it.

In the configuration according to FIG. 4 and FIGS. 6 through 9, the display 35 is shown with the display body component 15 in a raised position. The display body component is moved away from the joint 21 with respect to the second body component 25.

In FIGS. 6 and 7, the interface body component 13 forms a triangular foot with the first body component 23 and the docking module 27. The height of the foot can be adjusted by changing the angle between the first and the second body components and changing the angle of the joint between the joint body 47, on which the joint connector is formed, and the rest of the docking module 27. In this position, the keyboard is very difficult to use. A separate keyboard must be used, or in this position the laptop can be set up to show a film or a picture show for which it is not necessary to use the interface.

For the height adjustment of the display body component 15 with respect to the second body component 25 a guide rail 45 is provided on the display body component 15, which is located in a slidable guide engagement with the second body component 25 (FIG. 7).

In the configuration of the inventive laptop according to FIGS. 8 and 9, the interface body component 13 is slightly raised on the back end close to the joint. This results in an ergonomic inclination of the keyboard. The elevation is due to the docking module 27 being plugged in below the first body component 23. The docking module is placed toward the back to create a stable base for the set-up display body component 15.

A similarly ergonomic inclination of the interface can be achieved without the docking module. That is, collapsible feet 29 are provided on the first body component 23 (FIGS. 7 and 10), which can be extended to achieve the inclined set-up of the interface body component 13.

In a special embodiment of the invention, as shown in FIGS. 8 and 9, the interface 13 can be shifted with respect to the first body component 23. To do so, the interface body component has a guide 43 (FIG. 9), which exists in a sliding guide relationship with the opposite piece on the first body component 23. The interface body component 13 can, however, be designed to be removable and then preferably—in the known manner for stationary PC's—be connected to the computer by a wireless connection. A battery is provided in the interface body component 13 for this purpose. In the case of such a keyboard which can be used independent of the computer collapsible feet are advantageously provided on the interface body component for the ergonomic raising of the back of the interface body component.

FIG. 11 shows a possible set which belongs together and together allows a more multi-use and flexible use of the laptop. The set comprises a computer module consisting of the first body component 23 with the interface body component 33, and the second body component 25, on which the display body component can be plugged. This also includes two display body components 15 and 15′ with different size displays, namely a 12″ TFT display 35 for on the road and a 17″ TFT display 35′ for use at the workstation. Further, this set also includes a docking module 27 (not shown) with additional drive, charging station and, possibly, additional components.

The set can optionally contain more than these components. For example, various interface body components can be included. FIGS. 12 and 13 show two different interface body components which, for example, thanks to an easy-to-use plug connection can be exchanged with the first body component 23 at any time. In addition to the docking module, a power module can be provided similar to the docking module, which can be connectible to the computer body in place of the docking module and which contains an additional battery pack.

Jacks for an external mouse, a webcam and similar accessories are advantageously provided in the side corner of the interface body component 13. They can also be provided under the interface body component on the side on the first body component 23. The indicators for charge control, charge status, on, internet connection, etc., and possibly a main switch for the computer are provided on the concave side of one of the joint axis bodies belonging to the second body component 25. This axis body turns along with the display with respect to the interface. So, when opening the laptop these switches and indicators are visible and can be used and viewed.

Inside the joint 21 wire connection between the CPU and the display exist on the one hand and between the interface and the data storage unit on the other. These wire connection are arranged and run in such a way that a plurality of them are involved with opening and closing the laptop without a loss of connection quality.

Departing from the shown examples, the docking module can be firmly attached to the rest of the laptop and swivel on the same axis to have the display and interface swivel with respect to each other. This would also permit a Y-arrangement of these three mutually articulated body components and setting up the display in a raised position, as well as separating the interface from the body component containing the display.

The mechanism shown in FIG. 14 is used to move and stop the display body component 15 on the second body component 25. On the inside of the second body component 25 hidden by the display body component 15 a slide 51 is provided which is movably mounted with respect to the second body component and can be fixed to the display body component 15. This slide 51 is parallel movably mounted. The parallel move is guaranteed by an adjustment plate 53, comprising a first rod 55 and a second rod 57. These two rods are interconnected on a swivel connection 59 and prestressed against each other via a spring 60. On their lower end points the two rods 55, 57 are guided in a link 61 of a glide plate 63. The swivel connection 59 is also guided in a vertical link 65 in the glide plate 63.

Guide pins 67 are provide on the glide plate which engage in short links 68 in two stop rails 69, 71 and run through a motion of the stop rails 69, 71. The stop rails in turn engage with pints 73 in oblique links 75 in an operating means 77. The operating means is movable using an operating means button 79, whereby the stop rails are moved toward each other against a spring force of a spring (not shown). When the operating means button 79 is released, the stop rails are pressed against each other and both engage in [one each] of a stop tooth 81, 83. These stop teeth 81, 83 are fixed to the slide 51.

1. Laptop with at least one first body component (23) for an interface (33) and one second body component (25) for a display (35) than can be swiveled on the axis of a joint (21) around the first body component (23) and connected to it, characterized by a third body component (27) which is flexibly connected to the other two body components (23, 25), so that these three body components can be opened in a Y-shaped fashion, whereby in this position two body components (23, 27) can be used as stands for the second body component (25) provided with the display (35).

2. Laptop according to claim 1, characterized in that the third body component is a docking module (27) which can be connected to the first body component (23), which [docking module] can comprise at least an AC-adapter and a drive.

3. Laptop according to claim 2, characterized in that the docking module (27) is provided with a flat body component and a plug-in body (41) to establish a plug-in connection with the first body component (23), and is connected around an axis which can be swiveled with the flat body component of the docking module (27).

4. Laptop according to one of the previous claims, characterized in that the flexibly connected parts (23, 25; 41, 27) resist pivoting in various tilt positions, e.g. are locked, clamped or fixable.

5. Laptop according to one of the claims 2 through 4, characterized in that the first body component (23), the second body component (25) and the docking module (15) can be opened in a Y-shaped fashion.

6. Laptop according to one of the claims 1 through 5, characterized in that the display (35) is provided in its own display body component (15), which is mounted on the second body component (25).

7. Laptop according to claim 6, characterized in that the display body component (15) is movably mounted away from the axis of the joint (21) to toward the axis of the joint (21) on the second body component (25).

8. Laptop according to claim 7, characterized in that at least one stop rail (69, 71) and at least one stop tooth (81, 83) interacting with it are connected to the first body component (25) and or to the display body component (15) so that the display body component (15) is established in a plurality of movement positions and can be released to be moved.

9. Laptop according to claim 8, characterized in that the stop rail (69, 71) is provided with a row of teeth (85), which row of teeth can be engaged with the stop tooth (81, 83) associated with the stop rail.

10. Laptop according to claim 9, characterized in that the stop rail (69, 71) can be moved oblique to the longitudinal extension of the row of teeth (85) and the engagement between the row of teeth (85) and the stop tooth (81, 83) can be achieved and released by sliding the stop rail (69, 71).

11. Laptop according to one of claims 8 through 10, characterized in that two stop rails (69, 71) and two stop teeth (81, 83) are present which stop rails can be moved toward and away from each other, and can be operated by a common operating means (77).

12. Laptop according to claim 11, characterized in that the two stop rails (69, 71) are prestressed against each other by a spring.

13. Laptop according to one of claims 8 through 12, characterized in that the stop tooth (81, 83) or the stop teeth are provided on the display body component, or on a component movable with the display body component.

14. Laptop according to one of claims 7 through 13, characterized in that the display body component (15) and the second body component (25) are mounted to each other by an adjustment plate (53), which adjustment plate (53) has a swivel connection between two rods (55, 57) forming the adjustment plate and one tilt point is present on each of the four ends of the rods (55, 57), whereby two of the tilt points are mounted on the display body component (15) or on a component movable with the display body component and two of the tilt points are mounted on the second body component (25) or on a component (63) movable together with the second body component.

15. Laptop according to claims 14, characterized in that two tilt points are mounted in links (61) inclined toward each other.

16. Laptop according to claim 14 or 15, characterized in that the rods of the adjustment plate are prestressed against each other with a spring (60).

17. Laptop according to one of claims 6 through 16, characterized in that the display body component (15) and the second body component (25) are interconnected with a removable plug connection.

18. Laptop according to one of the claims 1 through 17, characterized in that the interface (33) is provided in its own interface body component (13) which is mounted on the first body component (23).

19. Laptop according to claim 18, characterized in that the interface body component (13) is mounted away from the axis of the joint (21) and toward the axis of the joint (21) movably to the first body component (23).

20. Laptop according to one of the previous claims, characterized in that the interface body component (13) and the first body component (23) are interconnected by a removable plug connection.

21. Laptop according to the one of the previous claims 1 through 20, characterized in that the PC board with the CPU is arranged in the second body component (25).

22. Laptop according to claim 21, characterized in that the second body component (25) has a body shell made of metal.

23. Laptop according to one of the previous claims, characterized in that the docking module (27) is provided with sockets for an external interface, in particular for an external keyboard and an external mouse.

24. Laptop according to one of the claims 6 through 23, characterized in that the length and the width of the second body component (23) is smaller than the length and the width of the display body component (15) affixed to it.

25. Laptop according to one of the claims 18 through 24, characterized in that the length and the width of the first body component (23) is smaller than the length and the width of the interface housing (13) affixed to it.

26. Laptop according to one of the claims 24 or 25, characterized in that the docking module (27) has essentially the same length and the same width as the first body component (23) or the second body component (25).

27. Laptop with at least one first body component (23) for an interface (33) and second body component (25) connected to the first body component (23) around the axis of a joint (21) which can be swiveled with the first body component (23) for a display (35).
characterized in that the board with the CPU is provided in the second body component (25), the display (25) is housed in its own display body component (15) and is movably mounted and/or is replaceable away from the swivel axis of the joint (21) and to the swivel axis of the joint (21) on the second body component (25).

28. Laptop according to claim 27, characterized in that the body shell of the second body component (25) is made of metal.
